(19) United States
(12) Patent Application Publication
(10) Pub. No.: US 2022/0254714 A1
(43) Pub. Date: Aug. 11, 2022

(54) CAPACITOR AND METHOD FOR PRODUCING THE SAME

(71) Applicant: SHENZHEN GOODIX TECHNOLOGY CO., LTD., Shenzhen (CN)

(72) Inventors: Bin LU, Shenzhen (CN); Jian SHEN, Shenzhen (CN)

(21) Appl. No.: 17/729,845

(22) Filed: Apr. 26, 2022

Related U.S. Application Data
(63) Continuation of application No. PCT/CN2020/082562, filed on Mar. 31, 2020.

(51) Int. Cl. H01L 23/522; H01L 49/02; H01G 4/30

(52) U.S. Cl. CPC H01L 23/5223; H01L 23/5226; H01G 4/30; H01L 28/87; H01L 28/84; H01L 28/91

(57) ABSTRACT

The present application provides a capacitor and a method for producing the same The capacitor includes: a multi-wing structure, including N groups of wing structures and N support structures, each group of the wing structures includes M wing structures arranged in parallel, M limit slots are formed on an outer side wall of the support structure, the M wing structures are fixed on outside of the support structure through the M limit slots, respectively, and M and N are positive integers; a laminated structure, covering the multi-wing structure and including at least one dielectric layer and a plurality of conductive layers; at least one first external electrode, electrically connecting to part or all of the odd-number conductive layers in the plurality of conductive layers; and at least one second external electrode, electrically connecting to part or all of even-number conductive layers in the plurality of conductive layers.

### CROSS-REFERENCE TO RELATED APPLICATIONS

This application is a continuation of International Application No. PCT/CN2020/082562, filed on Mar. 31, 2020, the disclosure of which is hereby incorporated by reference in its entirety.

### TECHNICAL FIELD

The present application relates to the field of capacitors, and in particular, to a capacitor and a method for producing the same.

### BACKGROUND

A capacitor may play a role of bypassing, filtering, decoupling, or the like in a circuit, which is an indispensable part of ensuring a normal operation of the circuit. With continuous development of a modern electronic system towards multi-function, high integration, low power consumption and miniaturization, traditional multi-layer ceramic capacitors (MLCC) have been unable to meet increasingly stringent requirements of small volume and high capacity of applications. How to prepare a capacitor with the small volume and high capacity has become an urgent technical problem to be resolved.

### SUMMARY

The present application provides a capacitor and a method for producing the same, which may prepare a capacitor with small volume and high capacitance density.

In a first aspect, a capacitor is provided, including:

a multi-wing structure, the multi-wing structure includes N groups of wing structures and N support structures, where each group of the wing structures includes M wing structures arranged in parallel, M limit slots are formed on an outer side wall of the support structure, the M wing structures are fixed on outside of the support structure through the M limit slots, respectively, and M and N are positive integers;

a laminated structure, the laminated structure covers the multi-wing structure and includes at least one dielectric layer and a plurality of conductive layers, and the at least one dielectric layer and the plurality of conductive layers form a structure that a conductive layer and a dielectric layer are alternated with each other;

at least one first external electrode, and the first external electrode is electrically connected to part or all of odd-number conductive layers in the plurality of conductive layers;

at least one second external electrode, and the second external electrode is electrically connected to part or all of even-number conductive layers in the plurality of conductive layers.

In some possible implementation manners, a side wall of the support structure is recessed inwards to form the M limit slots on the outer side wall of the support structure.

In some possible implementation manners, a side wall of the support structure protrudes outwards to form the M limit slots on the outer side wall of the support structure.

In some possible implementation manners, the support structure is columnar or sheet.

In some possible implementation manners, the support structure is hollow columnar or grooved.

In some possible implementation manners, the support structure is a T-shaped structure.

In some possible implementation manners, the capacitor further includes: an annular structure, and the annular structure is located outside of the N support structures and the N groups of wing structures.

In some possible implementation manners, the annular structure is formed by alternately stacking M first material layers and M−1 second material layers.

In some possible implementation manners, the wing structure is formed of the first material.

In some possible implementation manners, part or all of the conductive layers in the plurality of conductive layers are conformal with the multi-wing structure.

In some possible implementation manners, one part of the conductive layer in the plurality of conductive layers is conformal with the multi-wing structure, and the other part of the conductive layer is complementary to the multi-wing structure in shape.

In some possible implementation manners, the capacitor further includes:

an isolation ring located above outside of the N support structures, and the isolation ring is configured to isolate the laminated layer into two parts, an inner side and an outer side, and the first external electrode and the second external electrode are merely electrically connected to a part of the laminated structure located at the inner side of the isolation ring.

In some possible implementation manners, the capacitor further includes:

at least one first conductive via structure and at least one second conductive via structure,

where the first conductive via structure is located in the isolation ring, and the second conductive via structure is located outside the isolation ring near a center of the capacitor; or the first conductive via structure and/or the second conductive via structure is located outside the isolation ring near a center of the capacitor;

the first external electrode is electrically connected to part or all of odd-number conductive layers in the plurality of conductive layers through the at least one first conductive via structure, and the second external electrode is electrically connected to part or all of even-number conductive layers in the plurality of conductive layers through the at least one second conductive via structure.

In some possible implementation manners, the multi-wing structure is made of a conductive material, and the second external electrode is electrically connected to the multi-wing structure.

In some possible implementation manners, the multi-wing structure is formed of a material with a resistivity less than a threshold value, or a heavily doped conductive layer or a heavily doped conductive region is formed on a surface of the multi-wing structure.

In some possible implementation manners, the multi-wing structure includes a main body material and a conductive layer or a conductive region on a surface of the main body material, and the second external electrode is electrically connected with the multi-wing structure by being electrically connected with the main body material and the conductive layer or the conductive region on the surface of the main body material.

In some possible implementation manners, the capacitor further includes: a filling structure, the filling structure covers the laminated structure and fills a gap formed by the laminated structure.

In some possible implementation manners, the capacitor further includes: a substrate arranged under the multi-wing structure.

In some possible implementation manners, a wing structure in the N groups of wing structures in contact with the substrate has a discontinuous region between different support structures.

In some possible implementation manners, the substrate forms a substrate groove at the discontinuous region, and the laminated structure is further arranged inside the substrate groove.

In some possible implementation manners, the support structure extends into the substrate.

In some possible implementation manners, the capacitor further includes: an electrode layer arranged above the laminated layer, the electrode layer includes at least one first conductive region and at least one second conductive region separated from each other, the first conductive region forms the first external electrode, and the second conductive region forms the second external electrode.

In some possible implementation manners, the first external electrode and/or the second external electrode is electrically connected to the conductive layer in the plurality of conductive layers through an interconnection structure.

In some possible implementation manners, the interconnection structure includes at least one isolating layer, at least one first conductive via structure, and at least one second conductive via structure, where the first conductive via structure and the second conductive via structure penetrate the at least one insulating layer, the first external electrode is electrically connected to part or all of odd-number conductive layers in the plurality of conductive layers through the at least one first conductive via structure, and the second external electrode is electrically connected to part or all of even-number conductive layers in the plurality of conductive layers through the at least one second conductive via structure.

In some possible implementation manners, the conductive layer in the plurality of conductive layers includes at least one of following layers:

a heavily doped polysilicon layer, a metal silicide layer, carbon layer, a conductive polymer layer, an aluminum layer, a copper layer, a nickel layer, a tantalum nitride layer, a titanium nitride layer, an aluminum titanium nitride layer, a tantalum silicon nitride layer, and a tantalum carbon nitride layer.

In some possible implementation manners, a dielectric layer in the at least one dielectric layer includes at least one of following layers:

a silicon oxide layer, a silicon nitride layer, a silicon oxynitride layer, a metal oxide layer, a metal nitride layer, and a metal oxynitride layer.

In a second aspect, a method for producing a capacitor is provided, including:

preparing a multi-wing structure above a substrate, the multi-wing structure includes N groups of wing structures and N support structures, where each group of the wing structures includes M wing structures arranged in parallel, M limit slots are formed on an outer side wall of the support structure, the M wing structures are fixed on outside of the support structure through the M limit slots, respectively, and M and N are positive integers;

preparing a laminated structure on a surface of the multi-wing structure, the laminated structure covers the multi-wing structure and includes at least one dielectric layer and a plurality of conductive layers, and the at least one dielectric layer and the plurality of conductive layers form a structure that a conductive layer and a dielectric layer are alternated with each other;

preparing at least one first external electrode and at least one second external electrode, where the first external electrode is electrically connected to part or all of odd-number conductive layers in the plurality of conductive layers, and the second external electrode is electrically connected to part or all of even-number conductive layers in the plurality of conductive layers.

In some possible implementation manners, a side wall of the support structure is recessed inwards to form the M limit slots on the outer side wall of the support structure.

In some possible implementation manners, a side wall of the support structure protrudes outwards to form the M limit slots on the outer side wall of the support structure.

In some possible implementation manners, the support structure is columnar or sheet.

In some possible implementation manners, the support structure is hollow columnar or grooved

In some possible implementation manners, the support structure is a T-shaped structure.

In some possible implementation manners, the preparing a multi-wing structure above a substrate includes:

preparing a multi-layer structure above the substrate, the multi-layer structure includes M first material layers and M−1 second material layers, and the M first material layers and the M−1 second material layers form a structure that a first material layer and a second material layer are alternated with each other, the first material layer is different from the second material, and the first material layer is in direct contact with the substrate;

based on the multi-layer structure, preparing N first grooves extending along a first direction, and removing part of the second material exposed in the N first grooves, so as to form N hollow columnar or grooved first structures made of the first material, and the first direction is a direction perpendicular to the substrate;

depositing a third material on an upper surface of the multi-layer structure and in the N first structures;

based on the multi-layer structure, preparing N second grooves extending along the first direction, and removing the second material layer exposed in the N second grooves, thus forming N hollow columnar or grooved second structures made of the first material, so as to form the multi-wing structure.

In some possible implementation manners, the capacitor further includes: an annular structure, and the annular structure is located outside of the N support structures and the M wing structures.

In some possible implementation manners, the annular structure is formed by alternately stacking M first material layers and M−1 second material layers.

In some possible implementation manners, part or all of the conductive layers in the plurality of conductive layers are conformal with the multi-wing structure.

In some possible implementation manners, one part of the conductive layer in the plurality of conductive layers is conformal with the multi-wing structure, and the other part of the conductive layer is complementary to the multi-wing structure in shape.

In some possible implementation manners, the method further includes:

preparing an isolation ring, the isolation ring is located above outside of the N support structures, and the isolation ring is configured to isolate the laminated layer into two parts, an inner side and an outer side; and the first external electrode and the second external electrode are merely electrically connected to a part of the laminated structure located at the inner side of the isolation ring.

In some possible implementation manners, the method further includes:

preparing at least one first conductive via structure and at least one second conductive via structure,

where the first conductive via structure is located in the isolation ring, and the second conductive via structure is located outside the isolation ring near a center of the capacitor; or the first conductive via structure and/or the second conductive via structure is located outside the isolation ring near a center of the capacitor;

the first external electrode is electrically connected to part or all of odd-number conductive layers in the plurality of conductive layers through the at least one first conductive via structure, and the second external electrode is electrically connected to part or all of even-number conductive layers in the plurality of conductive layers through the at least one second conductive via structure.

In some possible implementation manners, the multi-wing structure is made of a conductive material, and the second external electrode is electrically connected to the multi-wing structure.

In some possible implementation manners, the multi-wing structure is formed of a material with a resistivity less than a threshold value, or a heavily doped conductive layer or a heavily doped conductive region is formed on a surface of the multi-wing structure.

In some possible implementation manners, the multi-wing structure includes a main body material and a conductive layer or a conductive region on a surface of the main body material, and the second external electrode is electrically connected with the multi-wing structure by being electrically connected with the main body material and the conductive layer or the conductive region on the surface of the main body material.

In some possible implementation manners, the method further includes:

preparing a filling structure, the filling structure covers the laminated structure and fills a gap formed by the laminated structure.

In some possible implementation manners, a wing structure in the N groups of wing structures in contact with the substrate has a discontinuous region between different support structures.

In some possible implementation manners, the substrate forms a substrate groove at the discontinuous region, and the laminated structure is further arranged inside the substrate groove.

In some possible implementation manners, the support structure extends into the substrate.

In some possible implementation manners, the preparing at least one first external electrode and at least one second external electrode includes:

preparing an electrode layer above the laminated structure, the electrode layer includes at least one first conductive region and at least one second conductive region separated from each other, the first conductive region forms the first external electrode, and the second conductive region forms the second external electrode.

In some possible implementation manners, the method further includes:

preparing an interconnection structure, where the first external electrode and/or the second external electrode is electrically connected to the conductive layer in the plurality of conductive layers through the interconnection structure.

In some possible implementation manners, the interconnection structure includes at least one isolating layer, at least one first conductive via structure, and at least one second conductive via structure, where the first conductive via structure and the second conductive via structure penetrate the at least one insulating layer, the first external electrode is electrically connected to part or all of odd-number conductive layers in the plurality of conductive layers through the at least one first conductive via structure, and the second external electrode is electrically connected to part or all of even-number conductive layers in the plurality of conductive layers through the at least one second conductive via structure.

Therefore, in an embodiment of the present application, a multi-wing structure is used as a skeleton, and a laminated structure is arranged on the multi-wing structure, so that a surface area of the laminated structure may be increased, and a larger capacitance value may be obtained under a condition of a smaller device size (a capacitance chip size), thereby being capable of improving capacitance density of a capacitor formed by the laminated structure. Furthermore, in the embodiment of the present application, M limit slots are formed on an outer side wall of N support structures in the multi-wing structure, and M wing structures in the multi-wing structure are fixed on outside of the support structure through the M limit slots. In a wet release process and the subsequent cleaning process, the wing structure is not easy to fall off due to action of surface tension, so that mechanical stability and mechanical robustness of the M wing structures may be improved, and the mechanical stability of the multi-wing structure may be improved.

### BRIEF DESCRIPTION OF DRAWINGS

FIG. 1 is a schematic structural diagram of a capacitor according to an embodiment of the present application.

FIG. 2 is a schematic structural diagram of a limit slot according to an embodiment of the present application.

FIG. 3 is a schematic structural diagram of another limit slot according to an embodiment of the present application.

FIGS. 4-9 are schematic structural diagrams of a multi-wing structure according to different embodiments of the present application, respectively.

FIG. 10 is a schematic flow chart of a method for producing a capacitor according to an embodiment of the present application.

FIGS. 11A to 11L are schematic diagrams of a method for producing a capacitor according to an embodiment of the present application.

### DESCRIPTION OF EMBODIMENTS

The technical solution in embodiments of the present application will be described hereinafter with reference to the accompanying drawings.

It should be understood that a capacitor according to an embodiment of the present application may play a role of bypassing, filtering, decoupling, or the like in a circuit.

The capacitor in the current stage may be a 3D silicon capacitor which is a novel capacitor based on semiconductor wafer processing techniques. Compared with a traditional MLCC (multi-layer ceramic capacitor), the 3D silicon capacitor has advantages of small size, high precision, strong stability, and long lifetime. In a basic processing flow, a 3D structure with a high aspect ratio such as a deep via, a trench, a pillar shape, a wall shape, or the like is required to be first processed on a wafer or substrate, and then an insulating thin film and a low-resistivity conductive material are deposited on a surface of the 3D structure to produce a lower electrode, a dielectric layer and an upper electrode of the capacitor, sequentially.

In this context, the present application provides a novel capacitor structure and a method for producing the same, which may improve capacitance density of the capacitor.

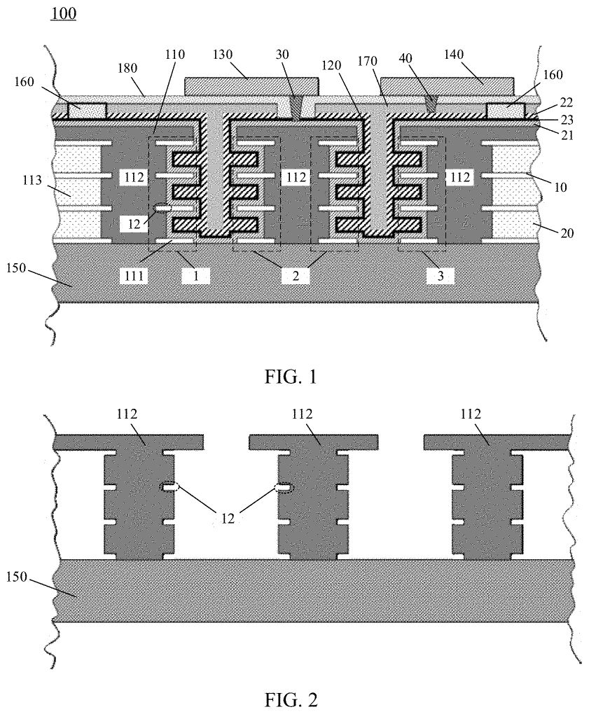

Hereinafter, a capacitor according to the embodiments of the present application will be introduced in detail with reference to FIGS. 1 to 9.

It should be understood that a capacitor in FIG. 1 is merely an example, a multi-wing structure included in the capacitor is not limited to that shown in FIGS. 1 to 9, and may be flexibly adjusted according to actual needs. Meanwhile, the number of wing structures included in the multi-wing structure and the number of support structures are merely an example, which is not limited to those shown in FIGS. 1 to 9, but may be flexibly set according to the actual needs.

It should be noted that, to facilitate understanding, in the embodiments shown below, for structures shown in different embodiments, the same structures are denoted by the same reference numbers, and a detailed illustration for the same structures is thus omitted for brevity.

FIG. 1 is a possible structural diagram of a capacitor 100 according to an embodiment of the present application. As shown in FIG. 1, the capacitor 100 includes a multi-wing structure 110, a laminated structure 120, at least one first external electrode 130 and at least one second external electrode 140.

Specifically, as shown in FIG. 1, in the capacitor 100, the multi-wing structure 110 includes N group(s) of wing structures 111 and N support structure(s) 112, where each group of the wing structures 111 includes M wing structure(s) 111 arranged in parallel, M limit slot(s) 12 are formed on an outer side wall of the support structure 112, the M wing structure(s) 111 are fixed on outside of the support structure 112 through the M limit slot(s) 12, respectively, and M and N are positive integers; the laminated structure 120 covers the multi-wing structure 110 and includes at least one dielectric layer and a plurality of conductive layers, and the at least one dielectric layer and the plurality of conductive layers form a structure that a conductive layer and a dielectric layer are alternated with each other; the first external electrode 130 is electrically connected to part or all of the odd-number conductive layers in the plurality of conductive layers; and the second external electrode 140 is electrically connected to part or all of even-number conductive layers in the plurality of conductive layers.

It should be noted that the M wing structure(s) 111 arranged in parallel and fixed on the outer side wall of one support structure 112 belong to the same group. In addition, the wing structures 111 in each group are correspondingly arranged, and the correspondingly arranged wing structures 111 are located on the same horizontal plane.

It should be understood that the limit slot 12 may tightly fix the wing structure 111 and make the M wing structure(s) 111 fixed on the outer side wall of one support structure 112 arranged in parallel. Width and depth of the limit slot 12 may be flexibly set according to a size of the wing structure 111, which is not limited in the present application.

In the embodiment of the present application, two adjacent conductive layers in the plurality of conductive layers are electrically isolated through the dielectric layer. A specific number of layers of the conductive layer and the dielectric layer may be flexibly configured according to the actual needs, as long as electrical isolation between the two adjacent conductive layers in the plurality of conductive layers is satisfied.

In addition, in the embodiment of the present application, M and N may be flexibly configured according to the actual needs.

It should be noted that in the embodiment of the present application, a multi-wing structure is used as a skeleton, and the laminated structure is arranged on the multi-wing structure, so that a surface area of the laminated structure may be increased, and a larger capacitance value may be obtained under a condition of a smaller device size (a capacitance chip size), thereby be capable of improving capacitance density of a capacitor formed by the laminated structure. Furthermore, in the embodiment of the present application, the multi-wing structure includes N group(s) of wing structures and N support structure(s). The multi-wing structure may have a larger surface area, thereby increasing the surface area of the laminated structure. Meanwhile, M limit slot(s) are formed on the outer side wall of the N support structure(s), and the M wing structure(s) are fixed on outside of the support structure through M the limit slot(s). In a wet release process and the subsequent cleaning process, the wing structure is not easy to fall off due to action of surface tension, so that mechanical stability and mechanical robustness of the M wing structure(s) may be improved, and the mechanical stability of the multi-wing structure may be improved.

In the embodiment of the present application, the surface area of the multi-wing structure may be understood as an area of a bottom wall and an inner side wall of the support structure, upper and lower surfaces and sides of the wing structure and other surfaces, which all may be used to attach the laminated structure.

In the embodiment of the present application, the multi-wing structure 110 is the skeleton, which may not be a part of the capacitor itself, that is, the multi-wing structure 110 may not be limited to selection of capacitor electrode materials, that is to say, material selection of the multi-wing structure 110 may be more flexible, so that a preparation process of the multi-wing structure 110 may be simplified.

It should be understood that an external electrode in the embodiment of the present application may also be referred to as a pad or an external pad.

Optionally, in the embodiment of the present application, a side wall of the support structure 112 is recessed inwards to form the M limit slot(s) 12 on the outer side wall of the support structure 112, as shown in FIG. 2. In addition, the M limit slot(s) may also be formed in other ways. For example, a side wall of the support structure 112 protrudes outwards to form the M limit slot(s) 12 on the outer side wall of the support structure 112.

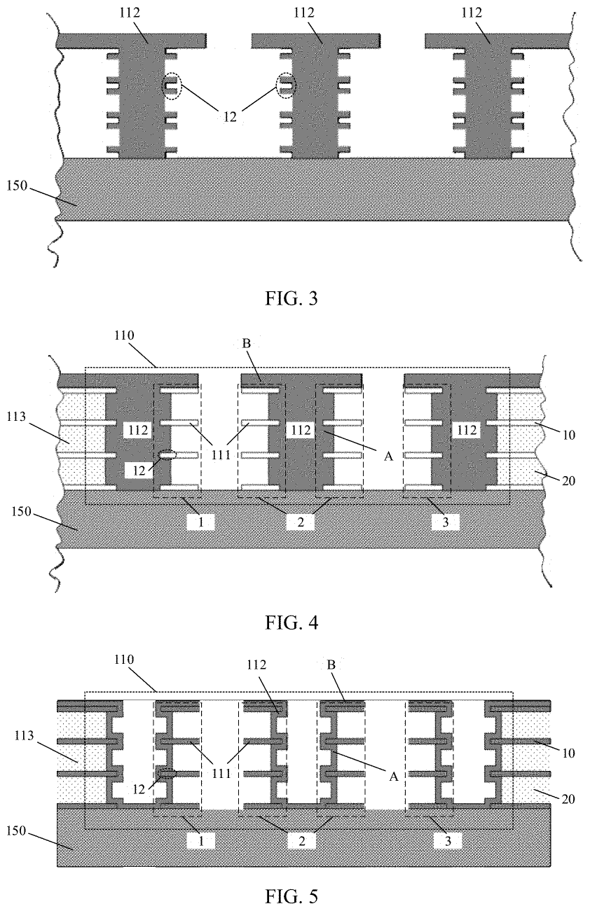

It should be noted that the above FIG. 2 and FIG. 3 merely take one support structure 112 of the N support structure(s) as an example for illustration, and all the support structures 112 in the N support structure(s) are also applicable.

Optionally, in some embodiments, the support structure 112 is a T-shaped structure, as shown in FIG. 1.

It should be noted that the support structure 112 of the T-shaped structure may be divided into a vertical part A and a horizontal part B. In some embodiments, the vertical part A may be columnar or sheet, and an outer edge of the horizontal part B is aligned with an outer edge of the wing-like structure 111, as shown in FIG. 4; in other embodiments, the vertical part A may be hollow columnar or grooved, and the outer edge of the horizontal part B is aligned with the outer edge of the wing-like structure 111, as shown in FIG. 5, and in this case, the laminated structure 120 may be arranged in the vertical part A of the support structure 112.

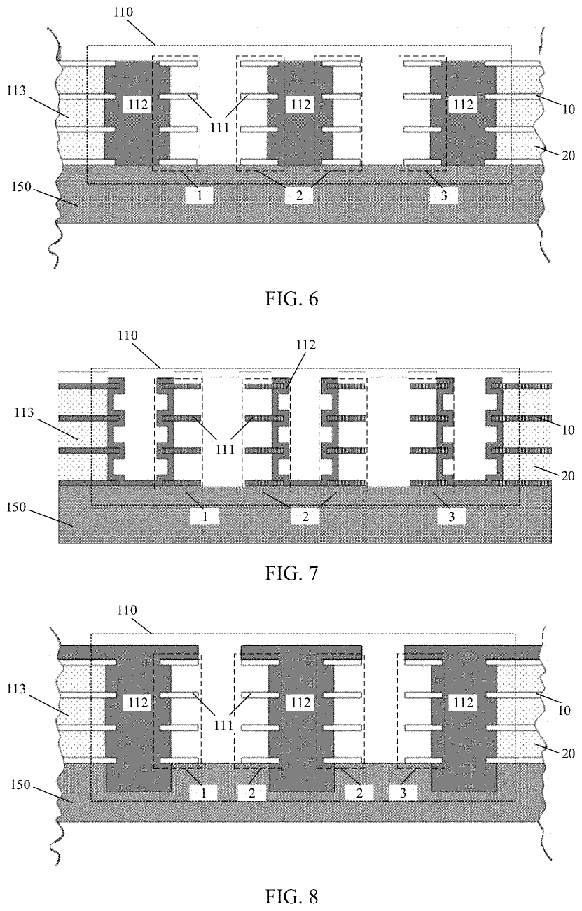

Optionally, in other embodiments, the support structure 112 is columnar or sheet, as shown in FIG. 6.

Optionally, in other embodiments, the support structure 112 is hollow columnar or grooved, as shown in FIG. 7.

It should be noted that the hollow columnar support structure 112 may also be referred to as a “barrel” support structure 112 or a “cup” support structure 112, which has a bottom structure and an annular side wall. The grooved support structure 112 may also be referred to as a “U-shaped” support structure 112, which has the bottom structure and two oppositely arranged side walls. That is, the bottom structure and the side walls of the support structure 112 may form a hollow region. Since the laminated structure 120 covers the support structure, that is to say, the laminated structure 120 may be provided in the hollow region.

Optionally, materials of the first external electrode 130 and the second external electrode 140 may be metals, such as copper, aluminum, or the like. Optionally, surfaces of the first external electrode 130 and the second external electrode 140 may be provided with low-resistivity Ti, TiN, Ta, TaN layers as adhesion layers and/or barrier layers to facilitate that the first external electrode 130 and the second external electrode 140 are adhered to other structures of the capacitor, or to facilitate a blocking function between the first external electrode 130 and the second external electrode 140 and other structures of the capacitor; in addition, the surfaces of the first external electrode 130 and the second external electrode 140 may also be provided with some metal layers, such as Ni, Pd (palladium), Au, Sn (tin), and Ag for subsequent wiring or welding processes.

Optionally, in the embodiment of the present application, the conductive layer in the plurality of conductive layers includes at least one of following layers:

a heavily doped polysilicon layer, a metal silicide layer, carbon layer, a conductive polymer layer, an aluminum layer, a copper layer, a nickel layer, a tantalum nitride layer, a titanium nitride layer, an aluminum titanium nitride layer, a tantalum silicon nitride layer, and a tantalum carbon nitride layer.

That is to say, in the laminated structure 120, materials of the conductive layer in the plurality of conductive layers may be heavily doped polysilicon, metal silicide, carbon, conductive polymer, metals such as Al, Cu, Ni, low-resistivity compounds such as tantalum nitride (TaN), titanium nitride (TiN), titanium aluminum nitride (TiAlN), tantalum silicon nitride (TaSiN), tantalum carbon nitride (TaCN), or the like, or the conductive layer in the plurality of conductive layers is a combination, a lamination and a composite structure of the above materials. That is to say, one conductive layer in the plurality of conductive layers may be one layer or include a plurality of laminations, and a certain conductive layer in the plurality of conductive layers may be a single layer formed of a single material, or it may be a composite layer formed of a plurality of materials.

It should be noted that materials and thicknesses of different conductive layers in the plurality of conductive layers may be the same or different. A specific conductive material and a layer thickness of the conductive layer in the plurality of conductive layers may be adjusted according to a capacitor capacitance, a frequency characteristic and loss and other requirements of a capacitor. Of course, the conductive layer in the plurality of conductive layers may also include some other conductive materials, which is not limited in the embodiment of the present application.

Optionally, in the embodiment of the present application, a dielectric layer in the at least one dielectric layer includes at least one of following layers:

a silicon oxide layer, a silicon nitride layer, a silicon oxynitride layer, a metal oxide layer, a metal nitride layer and a metal oxynitride layer.

That is to say, in the laminated layer structure 120, a material of the dielectric layer in the at least one dielectric layer may be silicon oxide, silicon nitride, silicon oxynitride, metal oxide, metal nitride and metal oxynitride. For example, SiO₂, SiN, SiON, or a high dielectric constant (high-k) materials, including Al₂O₃, HfO₂, ZrO₂, TiO₂, Y₂O₃, La₂O₃, HfSiO₄, LaAlO₃, SrTiO₃, LaLuO₃, or the like. One dielectric layer in the at least one dielectric layer may be one layer or include the plurality of laminations, and one dielectric layer in the at least one dielectric layer may be one material or a combination or a mixture of a plurality of materials.

It should be noted that materials and thicknesses of different dielectric layers in the at least one dielectric layer may be the same or different. A specific insulating material and a layer thickness of each dielectric layer in the at least one dielectric layer may be adjusted according to a capacitor capacitance, a frequency characteristic and loss and other requirements of a capacitor. Of course, a dielectric layer in the at least one dielectric layer may also include some other insulating materials, which is not limited in the embodiment of the present application.

In the embodiment of the present application, in the laminated structure 120, an order of the at least one dielectric layer may be: an ascending or descending order of a distance to the multi-wing structure 110 on the multi-wing structure 110. In the same way, an order of the plurality of conductive layers may also be: an ascending or descending order of a distance to the multi-wing structure 110 on the multi-wing structure 110. For ease of description, in the embodiment of the present application, an order of the at least one dielectric layer and the plurality of conductive layers is illustrated by taking an order of a distance from the multi-wing structure 110 in an ascending manner on the multi-wing structure 110 as an example.

Optionally, in the embodiment of the present application, the capacitor 100 further includes: a substrate 150, and the substrate 150 is arranged under the multi-wing structure 110, as shown in FIG. 1.

Optionally, in the embodiment of the present application, the support structure 112 may extend along a direction perpendicular to the substrate 150, and the wing structure 111 may extend along a direction parallel to the substrate 15.

It should be noted that in the embodiment of the present application, a thickness of the substrate 150 may also be flexibly set according to the actual needs. For example, when the thickness of the substrate 150 is too thick to meet requirements, the substrate 150 may be thinned. It may even completely remove the substrate 150.

It should be noted that the above FIG. 1 is a cross section along a longitudinal direction of the substrate.

Optionally, in the embodiment of the present application, the substrate 150 may be a silicon wafer, including monocrystalline silicon, polycrystalline silicon, and amorphous silicon. The substrate 150 may also be other semiconductor substrates, including silicon-on-insulator (SOI) wafers, silicon carbide (SiC), gallium nitride (GaN), and gallium arsenide (GaAs) and other compound semiconductor wafers of Group III-V elements. The substrate 150 may also be a metal plate, glass, ceramic, organic polymer, or other rigid substrates. In addition, a surface of the substrate 150 may include a bonding layer, an epitaxial layer, an oxide layer, a doped layer, or the like.

Optionally, in some embodiments, the wing structure 111 in contact with the substrate 150 between the different support structures 112 is continuous, and the substrate 150 has a flat surface in a region between the different support structures 112. In addition, other wing structures 111 between the different support structures 112 may also be continuous. For example, in case of an interruption through an annular groove between the different support structures 112, all the wing structures 111 between the support structures 112 are continuous.

Optionally, in other embodiments, the wing structure 111 in contact with the substrate 150 between the different support structures 112 is discontinuous, and the substrate 150 has a substrate groove 151 in the region between the different support structures 112.

Optionally, in some embodiments, the support structure 112 may also extend into the substrate 150.

Optionally, in some embodiments, a single wing structure 111 in a plurality of groups of the wing structures 111 may have a plurality of branches. In addition, in some embodiments, the support structure 112 in the plurality of support structures 112 may be provided with (have) at least one axis perpendicular to a direction of the substrate 150 in a hollow area thereof.

Optionally, in the embodiment of the present application, the capacitor 100 further includes an isolation ring 160 located above outside of the N support structure(s) 112, and the isolation ring 160 is configured to isolate the laminated structure 120 into two parts, an inner side and an outer side, and the first external electrode 130 and the second external electrode 140 are merely electrically connected to a part of the laminated structure 120 located at the inner side of the isolation ring 160, as shown in FIG. 1.

In some embodiments, the isolation ring 160 is located above an annular structure 113.

Optionally, in the embodiment of the present application, the capacitor 100 further includes: at least one first conductive via structure 30, and at least one second conductive via structure 40, where the first external electrode 130 is electrically connected to some or all of odd-number conductive layers in the plurality of conductive layers through the at least one first conductive via structure 30, and the second external electrode 140 is electrically connected to part or all of even-number conductive layers in the plurality of conductive layers through the at least one second conductive via structure 40.

Optionally, in some embodiments, the first conductive via structure 30 is located in the isolation ring 160, and the second conductive via structure 40 is located outside the isolation ring 160 near a center of the capacitor 100.

Optionally, in other embodiments, the first conductive via structure 30 and/or the second conductive via structure 40 are located outside the isolation ring 160 near the center of the capacitor 100. For example, as shown in FIG. 1, the first conductive via structure 30 and the second conductive via structure 40 are both located outside the isolation ring 160 near the center of the capacitor 100.

It should be noted that at an edge of the capacitor 100 or a capacitance chip, due to insufficient insulating capacity of air, air breakdown is prone to occur between the laminated structure 120 and the annular structure 113, thus resulting in a decreased performance of the capacitor. Arrangement of the isolation ring 160 may make an area of the laminated structure 120 outside the isolation ring 160 not constitute an electrode plate of the capacitor 100, thereby avoiding occurrence of a problem of the air breakdown between the laminated structure 120 and the annular structure 113 at the edge of the capacitor 100.

Optionally, in some embodiments, in the laminated structure 120, part or all of the conductive layers in the plurality of conductive layers are conformal with the multi-wing structure 110.

Optionally, in other embodiments, in the laminated structure 120, one part of the conductive layer in the plurality of conductive layers is conformal with the multi-wing structure 110, and the other part of the conductive layer is complementary to the multi-wing structure 110 in shape.

For example, as shown in FIG. 1, the multi-wing structure 110 includes three groups of the wing structures 111 and three support structures 112. The three groups of the wing structures 111 are denoted as group 1, group 2, and group 3 from left to right. Each group includes 4 wing structures 111, where the wing structure 111 in group 1 is merely fixed on an outer side wall near a right side of the corresponding support structure 112, the wing structure 111 in group 2 is fixed around the outer side wall of the corresponding support structure 112, and the wing structure 111 in group 3 is merely fixed on the outer side wall near a left side of the corresponding support structure 112. The laminated structure 120 includes two conductive layers and one dielectric layer, such as a conductive layer 21 and a conductive layer 22, and a dielectric layer 23 shown in FIG. 1. Specifically, as shown in FIG. 1, the conductive layer 21 is in direct contact with the multi-wing structure 110, that is, the conductive layer 21 is arranged on a surface of the multi-wing structure 110 and covers the multi-wing structure 110, and the conductive layer 21 is conformal to the multi-wing structure 110; the conductive layer 22 is arranged above the conductive layer 21, and the conductive layer 22 is complementary to the multi-wing structure 110 in shape; the dielectric layer 23 is arranged between the conductive layer 21 and the conductive layer 22 to electrically isolate the conductive layers 21 and the conductive layer 22, and the dielectric layer 23 is also conformal to the multi-wing structure 110.

It should be noted that the conductive layer 21 in the laminated structure 120 is conformal to the multi-wing structure 110, and it can be understood that the conductive layer 21 may have the same or substantially the same outline as the multi-wing structure 110, so that the conductive layer 21 may cover a region of the multi-wing structure 110 in contact with the conductive layer 21, and thus the laminated structure 21 may obtain a larger surface area based on the multi-wing structure 110, thereby improving the capacitance density of the capacitor. In the same way, the dielectric layer 23 is also conformal to the multi-wing structure 110, and the dielectric layer 23 may also have the same or substantially the same outline as the multi-wing structure 110. The conductive layer 22 is complementary to the multi-wing structure 110 in shape, and it can be understood that a combination of the conductive layer 22 and the multi-wing structure 110 may form a structure without a gap or cavity inside, thus improving the structural integrity and the mechanical stability of the capacitor.

Optionally, in some embodiments, the multi-wing structure 110 is made of a conductive material, and the second external electrode 140 is electrically connected to the multi-wing structure 110. That is, in the case that the multi-wing structure 110 is conductive, the multi-wing structure 110 may also be used as an electrode plate of the capacitor 100.

Optionally, in other embodiments, the multi-wing structure 110 includes a main body material and a conductive layer or a conductive region on a surface of the main body material, and the second external electrode 140 is electrically connected with the multi-wing structure 110 by being electrically connected with the conductive layer or conductive region.

It should be noted that in the case that the second external electrode 140 is also electrically connected to the multi-wing structure 110, an electrical isolation is needed to be performed between the multi-wing structure 110 and the laminated structure 120, for example, a dielectric layer is provided between the multi-wing structure 110 and the laminated structure 120.

Optionally, the multi-wing structure 110 is conductive, and it can be understood that the multi-wing structure 110 is formed of a material with a resistivity less than a threshold value, or a heavily doped conductive layer or conductive region with a resistivity less than a threshold value is formed on a surface of the multi-wing structure 110.

For example, the multi-wing structure 110 may be doped to form a p++-type or n++-type low-resistivity conductive layer or conductive region.

For another example, a low-resistivity conductive material is deposited on the surface of the multi-wing structure 110, such as using a PVD or ALD process to deposit TiN and/or TaN and/or Pt and other metals, or using a CVD process to deposit heavily doped polysilicon, metal tungsten, and carbon materials.

It should be understood that a material with the resistivity less than the threshold value may be regarded as the conductive material.

It should be noted that the multi-wing structure 110 is formed of the material with the resistivity less than the threshold value, which may ensure that the multi-wing structure 110 is conductive, that is, the multi-wing structure 110 may be used as an electrode plate of the capacitor 100.

Optionally, in the embodiment of the present application, the capacitor 100 further includes: a filling structure 170, and the filling structure 170 covers the laminated structure 120 and fills a cavity or a gap formed by the laminated structure 120, as shown in FIG. 1. Thus, the structural integrity and the mechanical stability of the capacitor may be improved.

Optionally, in some embodiments, the filling structure 170 is complementary to the laminated structure 120 in shape. For example, the filling structure 170 may be structurally complementary to the laminated structure 120, and a combination of the two may form a structure without a gap or cavity inside, thus improving the structural integrity and the mechanical stability of the capacitor.

It should be noted that a material of the filling structure 170 may be a conductive material, such as metallic tungsten, or some other materials, which is not limited in the present application.

Optionally, in the case that the material of the filling structure 170 is the conductive material, the filling structure 170 may also be used as an electrode plate of the capacitor 100.

Optionally, in the embodiment of the present application, the first external electrode 130 and/or the second external electrode 140 is electrically connected to the conductive layer in the plurality of conductive layers through the interconnection structure 180.

Optionally, the interconnection structure 180 includes at least one first conductive via structure 30, at least one second conductive via structure 40, and at least one insulating layer 50, where the first conductive via structure 30 and the second conductive via structure 40 penetrate the at least one insulating layer 50, the first external electrode 130 is electrically connected to part or all of odd-number conductive layers in the plurality of conductive layers through the at least one first conductive via structure 30, and the second external electrode 140 is electrically connected to part or all of even-number conductive layers in the plurality of conductive layers through the at least one second conductive via structure 40. Specifically, as shown in FIG. 1, the interconnect structure 180 is arranged above the filling structure 170.

It should be noted that the at least one insulating layer 50 may also be referred to as an inter-metal dielectric layer (IMD) or an inter-layer dielectric layer (ILD). In addition, the at least one insulating layer 50 and the isolation ring 160 have the same material. In other words, the at least one insulating layer 50 and the isolation ring 160 may be formed in the same step.

Optionally, a material of the at least one insulating layer 50 may be an organic polymer material, including polyimide, parylene, benzocyclobutene (BCB), or the like; or some inorganic materials, including spin on glass (SOG), undoped silicon glass (USG), boro-silicate glass (BSG), phospho-silicate glass (PSG), boro-phospho-silicate glass (BPSG), tetraethyl orthosilicate (TEOS), silicon oxide, nitride, carbide, ceramic; and it may also be a combination or a lamination of the above materials.

Optionally, the materials of the first conductive via structure 30 and the second conductive via structure 40 may be made of the low-resistivity conductive materials, such as heavily doped polysilicon, tungsten, Ti, TiN, Ta, TaN, or the like.

It should be understood that shape and number of the first conductive via structure 30 and the second conductive via structure 40 may be specifically determined according to a manufacturing process of the capacitor 100, which is not limited in the embodiment of the present application.

Optionally, in some embodiments, the at least one first external electrode 130 and the at least one second external electrode 140 are arranged above the multi-wing structure 110. Optionally, the capacitor 100 further includes: an electrode layer arranged above the multi-wing structure 110, and the electrode layer includes at least one first conductive region and at least one second conductive region separated from each other, the first conductive region forms the first external electrode 130, and the second conductive region forms the second external electrode 140, specifically as shown in FIG. 1. That is, the at least one first external electrode 130 and the at least one second external electrode 140 may be formed by one etching, which reduces etching steps.

Specifically, as shown in FIG. 1, the electrode layer is arranged above the interconnect structure 180, the first external electrode 130 is electrically connected to the conductive layer 21 through the first conductive via structure 30, and the second external electrode 140 is electrically connected to the conductive layer 22 through the second conductive via structure 40.

Optionally, in some embodiments, as shown in FIG. 4 to FIG. 7, the multi-wing structure 110 is arranged above the substrate 150, the multi-wing structure 110 includes three groups of the wing structures 111 and three support structures 112. The three groups of the wing structures 111 are denoted as group 1, group 2, and group 3 from left to right. Each group includes 4 wing structures 111, where the wing structure 111 in group 1 is merely fixed on an outer side wall near a right side of the corresponding support structure 112, the wing structure 111 in group 2 is fixed around the outer side wall of the corresponding support structure 112, and the wing structure 111 in group 3 is merely fixed on the outer side wall near a left side of the corresponding support structure 112. The wing structure 111 (that is, the wing structure at the bottom) in contact with the substrate 150 in different groups has a discontinuous region between the different support structures 112, and the substrate 150 has a flat surface in the discontinuous region. That is, in the discontinuous region, the laminated structure 120 may be directly in contact with the substrate 150.

Optionally, in another embodiment, as shown in FIG. 8, the multi-wing structure 110 is arranged above the substrate 150, which is similar to embodiments shown in FIG. 4 to FIG. 7, the multi-wing structure 110 includes three groups of the wing structures 111 and three support structures 112. The three groups of the wing structures 111 are denoted as group 1, group 2, and group 3 from left to right. Each group includes 4 wing structures 111, where the wing structure 111 in group 1 is merely fixed on an outer side wall near a right side of the corresponding support structure 112, the wing structure 111 in group 2 is fixed around the outer side wall of the corresponding support structure 112, and the wing structure 111 in group 3 is merely fixed on the outer side wall near a left side of the corresponding support structure 112. However, a main difference from the embodiments shown in FIG. 4 to FIG. 7 is that the support structure 112 in the three support structures 112 extends into the substrate 150. Thus, a side wall area of the support structure 112 may be increased, a surface area of the laminated structure 120 may be increased, and a capacitance density may be increased. At the same time, the mechanical stability of the multi-wing structure 110 may also be improved.

It should be noted that the present application does not limit a depth at which the support structure 112 in FIG. 8 extends into the substrate 150.

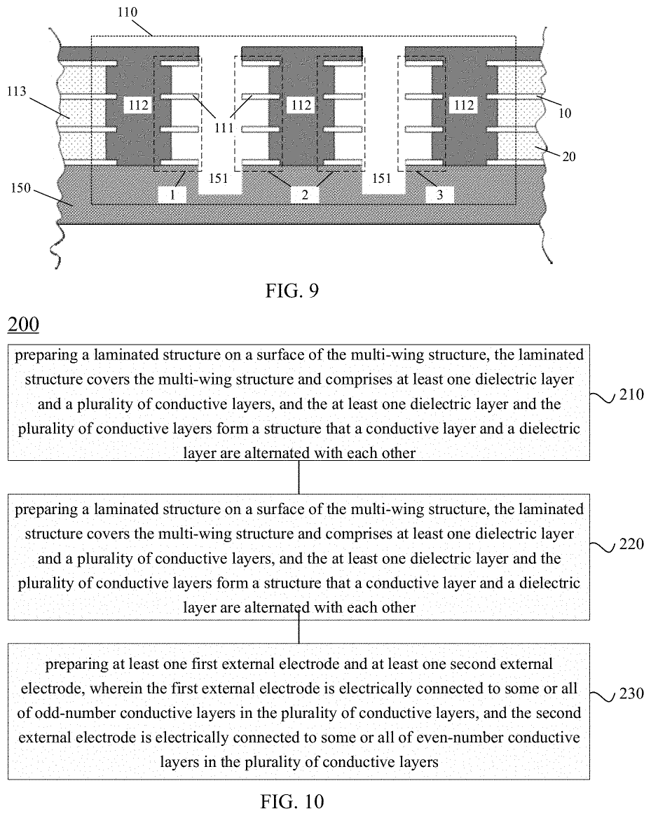

Optionally, in another embodiment, as shown in FIG. 9, the multi-wing structure 110 is arranged above the substrate 150, which is similar to embodiments shown in FIG. 4 to FIG. 7, the multi-wing structure 110 includes three groups of the wing structures 111 and three support structures 112. The three groups of the wing structures 111 are denoted as group 1, group 2, and group 3 from left to right. Each group includes 4 wing structures 111, where the wing structure 111 in group 1 is merely fixed on an outer side wall near a right side of the corresponding support structure 112, the wing structure 111 in group 2 is fixed around the outer side wall of the corresponding support structure 112, and the wing structure 111 in group 3 is merely fixed on the outer side wall near a left side of the corresponding support structure 112. However, a main difference from the embodiments shown in FIG. 4 to FIG. 7 is that the wing structure 111 in contact with the substrate 150 in different groups has a discontinuous region between the different support structures 112, and the substrate 150 has a substrate groove formed at the discontinuous region. That is to say, the laminated structure 120 may be arranged inside the substrate groove 151, so that a surface area of the laminated structure 120 may be increased, and a capacitance density may be increased. At the same time, the mechanical stability of the multi-wing structure 110 may also be improved.

It should be noted that the present application does not limit a depth of the substrate groove 151 in FIG. 9.

Optionally, the above solution of the multi-wing structure 110 included in the capacitor 100 in FIG. 8 and FIG. 9 may be combined. In the solution, a depth of the support structure 112 extending into the substrate 150 and a depth of the substrate groove 151 may be the same or different.

Optionally, in the embodiment of the present application, the capacitor 100 further includes the annular structure 113 located outside of the N support structure(s) 111 and the N group(s) of the wing structures 111, as shown in FIG. 1, FIG. 4 to FIG. 9. The annular structure 113 may support and protect the support structure 112 to a certain extent. At the same time, the annular structure 113 may also form an edge region of the capacitance chip to facilitate subsequent preparation of the capacitor 100.

Optionally, the annular structure 113 is formed by alternately stacking M first material layer(s) 10 and M−1 second material layer(s) 20, and as shown in FIG. 1, FIG. 4 to FIG. 9, M=4, that is, the annular structure 113 is formed by alternately stacking four first material layers 10 and three second material layers 20.

Optionally, the wing structure 111 in the multi-wing structure 110 is formed of the first material. In addition, the wing structure 111 in the multi-wing structure 110 may also be formed of other materials, which is not limited in the present application.

Optionally, the first material or the second material may be silicon (including monocrystalline silicon, polycrystalline silicon, amorphous silicon), silicon oxide, silicon nitride or silicon carbide, silicon-containing glass (including undoped silicon glass (USG), boro-silicate glass (BSG), phospho-silicate glass (PSG), boro-phospho-silicate glass (BPSG)), metals such as aluminum (Al), copper (Cu), nickel (Ni), or metal nitrides, carbides, carbon, organic polymers, or a combination or a lamination of the above materials.

It should be understood that the first material and the second material are a combination of two types of materials. The second material may be selectively removed with respect to the first material. Specifically, in the same corrosion or etching environment, a difference in corrosion (or etching) rates of the first material and the second material is greater than 5 times. That is, in some specific environments, the second material is more likely to be corroded (or etched) away with respect to the first material.

For example, the first material may be silicon, and the second material may be silicon oxide, and the silicon oxide may be removed and the silicon may be retained by a hydrofluoric acid solution or gas. For example, in a process of preparing N group(s) of the wing structures 111, the material of the support structure 112 and the wing structure 111 may be silicon, and the material between the different wing structures 111 in the same group may be silicon oxide, so that the hydrofluoric acid solution or gas is used to selectively remove the silicon oxide and retain the silicon to form a plurality of groups of the wing structures 111.

For another example, the first material may be silicon oxide, and the second material may be silicon. With a KOH, or a NaOH, or a tetra methyl ammonium hydroxide (TMAH) solution, or a xenon difluoride (XeF₂) gas, the silicon may be removed while retaining the silicon oxide. For example, in a process of preparing N group(s) of the wing structures 111, the material of the support structure 112 and the wing-like structure 111 may be the silicon oxide, and the material between the different the wing structures 111 in the same group may be the silicon, so that the KOH or the NaOH or the TMAH solution or the xenon difluoride (XeF₂) gas is used to selectively remove the silicon and retain the silicon oxide to form the plurality of groups of the wing structures 111.

For another example, the first material may be silicon oxide, and the second material may be silicon nitride, and a hot phosphoric acid solution may be used to quickly remove the silicon nitride and retain the silicon oxide. For example, in a process of preparing a plurality of groups of the wing structures 111, the material of the support structure 112 and the wing structure 111 may be the silicon oxide, and the material between the different wing structures 111 in the same group may be the silicon nitride, so that the hot phosphoric acid solution is used to selectively remove the silicon nitride and retain the silicon oxide, so as to form the plurality of groups of the wing structures 111.

It should be noted that in the embodiment of the present application, the laminated structure 120 may form a step structure in an upper region of the annular structure 113, so as to expose different conductive layers in the plurality of conductive layers through different step surfaces of the step structure. Thus, the first external electrode 130 may be electrically connected to part or all of odd-number conductive layers in the plurality of conductive layers through the step structure, and the second external electrode 140 may also be electrically connected to part or all of even-number conductive layers in the plurality of conductive layers through the step structure. In this structure, a plurality of “conductive-dielectric-conductive” basic capacitance units formed by the laminated structure 120 may be connected in parallel to form a large-capacity capacitor.

In the embodiment of the present application, the first external electrode 130 is electrically connected to part or all of odd-number conductive layers in the plurality of conductive layers, and the second external electrode 140 is electrically connected to part or all of even-number conductive layers in the plurality of conductive layers. Thus, in some scenarios, for different first external electrodes 130 and different second external electrodes 140, the laminated structure 120 may form capacitors with different capacitance values.

As an example, it is assumed that the capacitor 100 includes two first external electrodes and two second external electrodes, the two first external electrodes are denoted as a first external electrode A and a first external electrode B, respectively, and the two second external electrodes are denoted as a second external electrode C and a second external electrode D, respectively, and the laminated structure includes five conductive layers and four dielectric layers, and the five conductive layers are denoted as a conductive layer 1, a conductive layer 2, a conductive layer 3, a conductive layer 4 and a conductive layer 5, respectively, and the four dielectric layers are denoted as a dielectric layer 1, a dielectric layer 2, a dielectric layer 3, and a dielectric layer 4, respectively.

If the first external electrode A is electrically connected to the conductive layer 1 and the conductive layer 3, the first external electrode B is electrically connected to the conductive layer 1, the conductive layer 3 and the conductive layer 5, and the second external electrode C is electrically connected to the conductive layer 2 and the conductive layer 4, and the second external electrode D is also electrically connected to the conductive layer 2 and the conductive layer 4, for capacitors corresponding to the first external electrode A and the second external electrode C, the conductive layer 1 and the conductive layer 2 form a capacitor 1, a capacitance value thereof is denoted as C1, the conductive layer 2 and the conductive layer 3 form a capacitor 2, a capacitance value thereof is denoted as C2, the conductive layer 3 and the conductive layer 4 form a capacitor 3, a capacitance value thereof is denoted as C3, and the capacitor 1, the capacitor 2 and the capacitor 3 are connected in parallel, and a capacitance value of an equivalent capacitor i thereof is denoted as Ci, and thus Ci=C1+C2+C3; and for capacitors corresponding to the first external electrode B and the second external electrode D, the conductive layer 1 and the conductive layer 2 form a capacitor 1, and a capacitance value thereof is denoted as C1, the conductive layer 2 and the conductive layer 3 form a capacitor 2, and a capacitance value thereof is denoted as C2, the conductive layer 3 and the conductive layer 4 form a capacitor 3, and a capacitance value thereof is denoted as C3, the conductive layer 4 and the conductive layer 5 form a capacitor 4, and a capacitance value thereof is denoted as C4, and the capacitor 1, the capacitor 2, the capacitor 3 and the capacitor 4 are connected in parallel, and a capacitance value of an equivalent capacitor j thereof is denoted as Cj, and thus Cj=C1+C2+C3+C4. Of course, a similar series-parallel structure may also be formed for capacitors corresponding to the first external electrode A and the second external electrode D, a similar series-parallel structure may also be formed for capacitors corresponding to the first external electrode B and the second external electrode C. Details are not described herein again. Thus, the laminated structure 120 may form the capacitors with the different capacitance values.

If the first external electrode A is electrically connected to the conductive layer 1 and the conductive layer 5, the first external electrode B is electrically connected to the conductive layer 3 and the conductive layer 5, and the second external electrode C is electrically connected to the conductive layer 2 and the conductive layer 4, and the second external electrode D is also electrically connected to the conductive layer 4, for capacitors corresponding to the first external electrode A and the second external electrode C, the conductive layer 1 and the conductive layer 2 form a capacitor 1, a capacitance value thereof is denoted as C1, the conductive layer 2 and the conductive layer 4 form a capacitor 2, a capacitance value thereof is denoted as C2, and the capacitor 1 and the capacitor 2 are connected in parallel, and a capacitance value of an equivalent capacitor i thereof is denoted as Ci, and thus Ci=C1+C2; and for capacitors corresponding to the first external electrode B and the second external electrode D, the conductive layer 3 and the conductive layer 4 form a capacitor 3, and a capacitance value thereof is denoted as C3, the conductive layer 4 and the conductive layer 5 form a capacitor 4, and a capacitance value thereof is denoted as C4, and the capacitor 3 and the capacitor 4 are connected in parallel, and a capacitance value of an equivalent capacitor j thereof is denoted as Cj, and thus Cj=C3+C4. Thus, the laminated structure 120 may form the capacitors with the different capacitance values.

Preferably, the first external electrode 130 is electrically connected to part or all of odd-number conductive layers in the plurality of conductive layers; and the second external electrode 140 is electrically connected to part or all of even-number conductive layers in the plurality of conductive layers. Thus, it may give full play to an effect of the laminated structure to increase the capacitance density of the capacitor.

As an example, it is assumed that the capacitor 100 includes two first external electrodes and two second external electrodes, the two first external electrodes are denoted as a first external electrode A and a first external electrode B, respectively, and the two second external electrodes are denoted as a second external electrode C and a second external electrode D, respectively, and the laminated structure includes five conductive layers and four dielectric layers, and the five conductive layers are denoted as a conductive layer 1, a conductive layer 2, a conductive layer 3, a conductive layer 4 and a conductive layer 5, respectively, and the four dielectric layers are denoted as a dielectric layer 1, a dielectric layer 2, a dielectric layer 3, and a dielectric layer 4, respectively.

If the first external electrode A is electrically connected to the conductive layer 1, the conductive layer 3 and the conductive layer 5, the first external electrode B is electrically connected to the conductive layer 1, the conductive layer 3 and the conductive layer 5, and the second external electrode C is electrically connected to the conductive layer 2 and the conductive layer 4, and the second external electrode D is also electrically connected to the conductive layer 2 and the conductive layer 4, for capacitors corresponding to the first external electrode A and the second external electrode C, the conductive layer 1 and the conductive layer 2 form a capacitor 1, a capacitance value thereof is denoted as C1, the conductive layer 2 and the conductive layer 3 form a capacitor 2, a capacitance value thereof is denoted as C2, the conductive layer 3 and the conductive layer 4 form a capacitor 3, a capacitance value thereof is denoted as C3, the conductive layer 4 and the conductive layer 5 form a capacitor 4, a capacitance value thereof is denoted as C4, and the capacitor 1, the capacitor 2, the capacitor 3 and the capacitor 4 are connected in parallel, and a capacitance value of an equivalent capacitor i thereof is denoted as Ci, and thus Ci=C1+C2+C3+C4; and for capacitors corresponding to the first external electrode B and the second external electrode D, the conductive layer 1 and the conductive layer 2 form a capacitor 1, and a capacitance value thereof is denoted as C1, the conductive layer 2 and the conductive layer 3 form a capacitor 2, and a capacitance value thereof is denoted as C2, the conductive layer 3 and the conductive layer 4 form a capacitor 3, and a capacitance value thereof is denoted as C3, the conductive layer 4 and the conductive layer 5 form a capacitor 4, and a capacitance value thereof is denoted as C4, and the capacitor 1, the capacitor 2, the capacitor 3 and the capacitor 4 are connected in parallel, and a capacitance value of an equivalent capacitor j thereof is denoted as Cj, and thus Cj=C1+C2+C3+C4.

Therefore, in the embodiment of the present application, a multi-wing structure is used as a skeleton, and the laminated structure is arranged on the multi-wing structure, so that a surface area of the laminated structure may be increased, and a larger capacitance value may be obtained under a condition of a smaller device size (a capacitance chip size), thereby being capable of improving capacitance density of a capacitor formed by the laminated structure. Furthermore, in the embodiment of the present application, M limit slot(s) are formed on an outer side wall of the N support structure(s) in the multi-wing structure, and the M wing structure(s) in the multi-wing structure are fixed on outside of the support structure through the M limit slot(s). In a wet release process and the subsequent cleaning process, the wing structure is not easy to fall off due to action of surface tension, so that mechanical stability and mechanical robustness of the M wing structure(s) may be improved, and the mechanical stability of the multi wing structure is improved.

A capacitor according to the embodiments of the present application is described above, and a method for preparing a capacitor according to the embodiments of the present application will be described below. The method for preparing the capacitor according to the embodiments of the present application may prepare the capacitor according to the foregoing embodiments of the present application, and related descriptions in the following embodiments and the foregoing embodiments may be referred to each other.

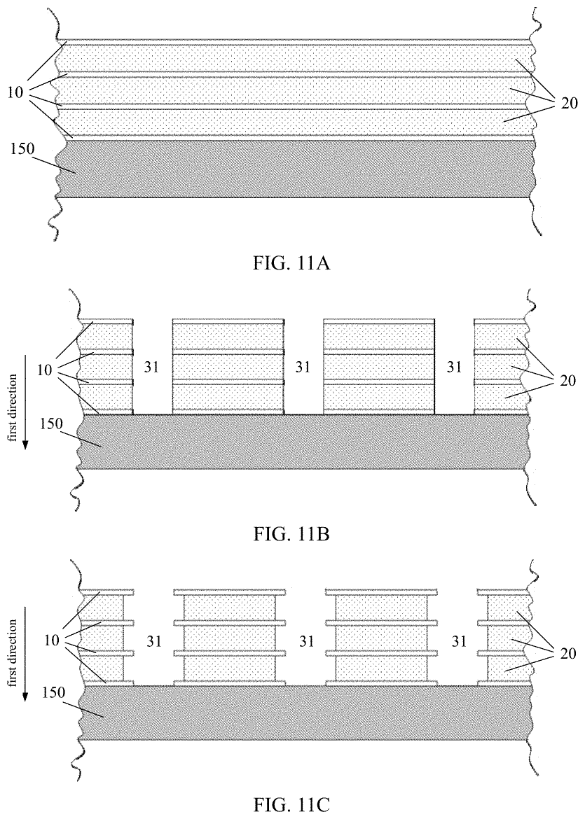

Hereinafter, a method for producing a capacitor according to the embodiments of the present application will be introduced in detail with reference to FIG. 10.

It should be understood that FIG. 10 is a schematic flow chart of a method for producing a capacitor according to the embodiment of the present application, but these steps or operations are merely examples, and other operations or variations of the various operations in FIG. 10 may also be performed in the embodiment of the present application.

FIG. 10 illustrates a schematic flow chart of a method 200 for producing a capacitor according to the embodiment of the present application. As shown in FIG. 10, the method 200 for producing the capacitor includes:

210, preparing a multi-wing structure above a substrate, the multi-wing structure includes N group(s) of wing structures and N support structure(s), where each group of the wing structures includes M wing structure(s) arranged in parallel, M limit slot(s) are formed on an outer side wall of the N support structure(s), the M wing structure(s) are fixed on outside of the support structure through the M limit slot(s), respectively, and M and N are positive integers;

220, preparing a laminated structure on a surface of the multi-wing structure, the laminated structure covers the multi-wing structure and includes at least one dielectric layer and a plurality of conductive layers, and the at least one dielectric layer and the plurality of conductive layers form a structure that a conductive layer and a dielectric layer are alternated with each other;

230, preparing at least one first external electrode and at least one second external electrode, where the first external electrode is electrically connected to part or all of odd-number conductive layers in the plurality of conductive layers, and the second external electrode is electrically connected to part or all of even-number conductive layers in the plurality of conductive layers.

Specifically, based on the above steps 210-230, a capacitor as shown in FIG. 1 may be prepared, or a capacitor prepared based on the multi-wing structure as shown in FIG. 2 to FIG. 9 may also be prepared.

It should be understood that an upper surface of each material layer described in steps 210-230 refers to a surface of the material layer that is substantially parallel to an upper surface of the substrate.

Optionally, in some embodiments, a side wall of the support structure 112 is recessed inwards to form the M limit slot(s) 12 on the outer side wall of the support structure 112.

Optionally, in other embodiments, a side wall of the support structure 112 protrudes outwards to form the M limit slot(s) 12 on the outer side wall of the support structure 112.

Optionally, in some embodiments, the support structure 112 is columnar or sheet.

Optionally, in some embodiments, the support structure 112 is hollow columnar or grooved.

Optionally, in some embodiments, the support structure 112 is a T-shaped structure.

Optionally, in some embodiments, the above step 210 may specifically include:

preparing a multi-layer structure above the substrate 150, the multi-layer structure includes M first material layer(s) 10 and M−1 second material layer(s) 20, and the M first material layer(s) 10 and the M−1 second material layer(s) 20 form a structure that a first material layer 10 and a second material layer 20 are alternated with each other, the first material layer is different from the second material, and the first material layer 10 is in direct contact with the substrate 150;

based on the multi-layer structure, preparing N first groove(s) extending along a first direction, and removing part of the second material exposed in the N first groove(s), so as to form N hollow columnar or grooved first structure(s) 31 made of the first material, and the first direction is a direction perpendicular to the substrate 150;

depositing a third material on an upper surface of the multi-layer structure and in the N first structure(s) 31;

based on the multi-layer structure, preparing N second groove(s) extending along the first direction, and removing the second material layer 20 exposed in the N second groove(s), thus forming N hollow columnar or grooved second structure(s) 32 made of the first material, so as to prepare the multi-wing structure 110.

A deposition method of the above first material and second material preferably uses chemical vapor deposition (CVD), or spin coating, spray coating, thermal oxidation, epitaxy, physical vapor deposition (PVD), atomic layer deposition (ALD), epitaxial growth and many other processes may also be used.

It should be noted that the third material and the first material may be the same material or different materials, which is not limited in the present application.

Optionally, the laminated structure 120 may be formed on the multi-wing structure 110 using various processes such as thermal oxidation, atomic layer deposition (ALD), chemical vapor deposition (CVD), or the like.

It should be understood that the second material may be selectively removed with respect to the first material. Specifically, in the same corrosion or etching environment, a difference in corrosion (or etching) rates of the first material and the second material is greater than 5 times. That is, in the same corrosion or etching environment, the corrosion (or etching) rate of the second material is at least 5 times the corrosion (or etching) rate of the first material.

Optionally, in some embodiments, part or all of the conductive layers in the plurality of conductive layers are conformal with the multi-wing structure 110.

Optionally, in some embodiments, one part of the conductive layer in the plurality of conductive layers is conformal with the multi-wing structure 110, and the other part of the conductive layer is complementary to the multi-wing structure 110 in shape.

Optionally, in some embodiments, the capacitor 100 further includes the annular structure 113 located outside of the N support structure(s) 111 and the N group(s) of the wing structures 111.

Optionally, the annular structure 113 is formed by alternately stacking M first material layer(s) 10 and M−1 second material layer(s) 20. Specifically, thicknesses of the first material layer 10 and the second material layer 20 may be adjusted according to a capacitance value, a frequency characteristic, a loss and other requirements of a capacitor.

Optionally, the M wing structure(s) 111 in the multi-wing structure 110 is formed of the first material.

It should be noted that the first material and the second material may specifically refer to the description of the above capacitor 100. For brevity, details are not described herein again.

Optionally, in some embodiments, the multi-wing structure 110 is made of a conductive material, and the second external electrode 140 is electrically connected to the multi-wing structure 110.

Optionally, in other embodiments, the multi-wing structure 110 includes a main body material and a conductive layer or a conductive region on a surface of the main body material, and the second external electrode 140 is electrically connected with the multi-wing structure 110 by being electrically connected with the conductive layer or the conductive region of the main body material and the surface of the main body material.

Optionally, the multi-wing structure 110 is formed of a material with a resistivity less than a threshold value, or a heavily doped conductive layer or a heavily doped conductive region is formed on a surface of the multi-wing structure 110

Optionally, in some embodiments, the method 200 further includes:

preparing the isolation ring 160, where the isolation ring 160 is located above outside of the N support structure(s) 112, and the isolation ring 160 is configured to isolate the laminated structure 120 into two parts, an inner side and an outer side, and the first external electrode 130 and the second external electrode 140 are merely electrically connected to a part of the laminated structure 120 located at the inner side of the isolation ring 160

Optionally, the isolation ring 160 is located above the annular structure 113.

Optionally, in some embodiments, the method 200 further includes:

preparing at least one first conductive via structure 30 and at least one second conductive via structure 40;

where the first conductive via structure 30 is located in the isolation ring 160, and the second conductive via structure 40 is located outside the isolation ring 160 near a center of the capacitor 100; or the first conductive via structure 30 and/or the second conductive via structure 40 is located outside the isolation ring 160 near the center of the capacitor 100;

the first external electrode 130 is electrically connected to part or all of odd-number conductive layers in the plurality of conductive layers through the at least one first conductive via structure 30, and the second external electrode 140 is electrically connected to part or all of even-number conductive layers in the plurality of conductive layers through the at least one second conductive via structure 40.

Optionally, in some embodiments, the method 200 further includes:

preparing a filling structure 170, the filling structure 170 covers the laminated structure 120 and fills a gap formed by the laminated structure 120.

Optionally, in some embodiments, the wing structure 111 in contact with the substrate 150 in a plurality of multi-wing structures 111 has a discontinuous region between the different support structures 112.

Optionally, in some embodiments, the substrate 150 forms a substrate groove 151 at the discontinuous region, and the laminated structure 120 is further arranged inside the substrate groove 151.

Optionally, in some embodiments, the support structure 112 extends into the substrate 150.

Optionally, in some embodiments, the above step 230 may specifically include:

preparing an electrode layer above the laminated structure 120, the electrode layer includes at least one first conductive region and at least one second conductive region separated from each other, the first conductive region forms the first external electrode 130, and the second conductive region forms the second external electrode 140.

Optionally, the first external electrode 130 and/or the second external electrode 140 may be formed using processes such as PVD, electroplating, chemical plating.

Optionally, in some embodiments, the method 200 further includes:

preparing an interconnection structure 180, where the first external electrode 130 and/or the second external electrode 140 is electrically connected to the conductive layer in the plurality of conductive layers through the interconnection structure 180.

Optionally, the interconnection structure 180 includes at least one first conductive via structure 30, at least one second conductive via structure 40, and at least one insulating layer 50, where the first conductive via structure 30 and the second conductive via structure 40 penetrate the at least one insulating layer 50, the first external electrode 130 is electrically connected to part or all of odd-number conductive layers in the plurality of conductive layers through the at least one first conductive via structure 30, and the second external electrode 140 is electrically connected to part or all of even-number conductive layers in the plurality of conductive layers through the at least one second conductive via structure 40.

Optionally, the at least one insulating layer 50 may be deposited and formed using processes such as spin coating, spray coating, physical vapor deposition (PVD), chemical vapor deposition (CVD).

Optionally, the first conductive via structure 30 and the second conductive via structure 40 may be formed by using processes such as PVD, metal-organic chemical vapor deposition (MOCVD), ALD in the via.

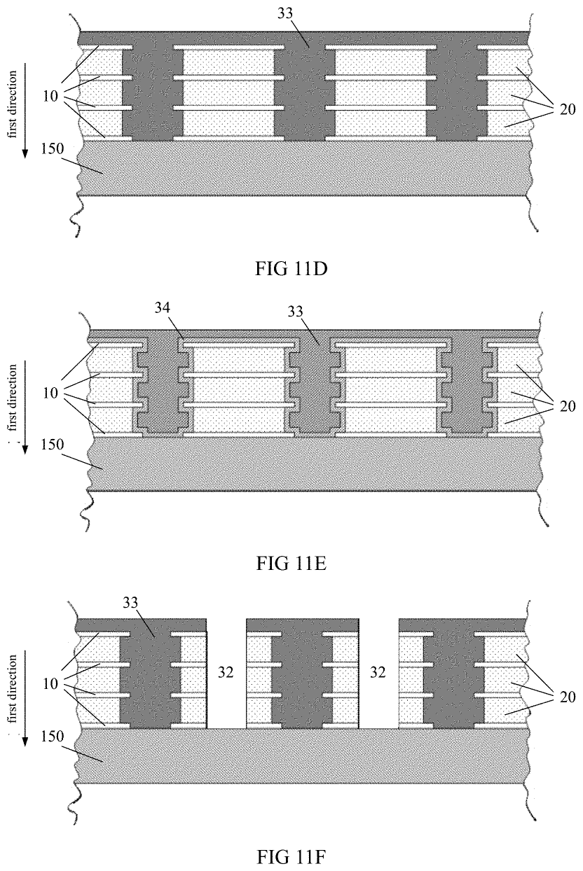

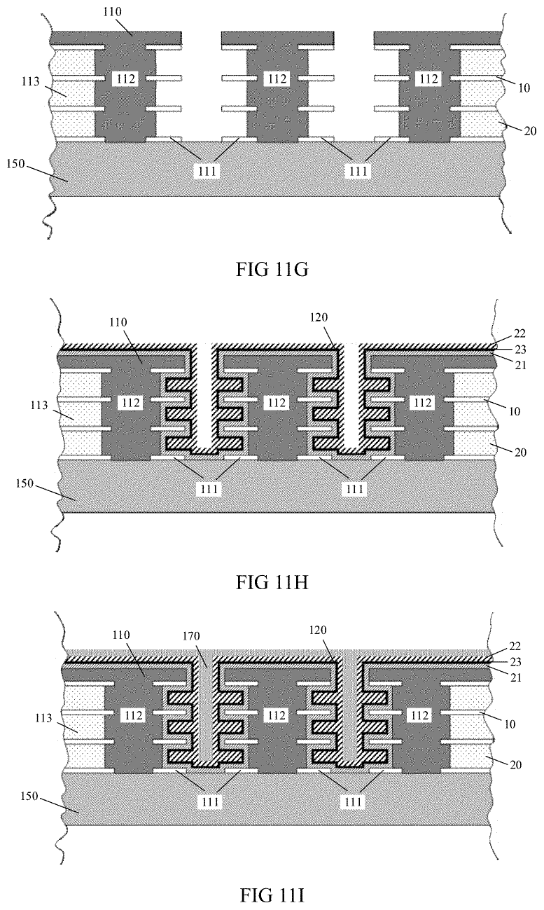

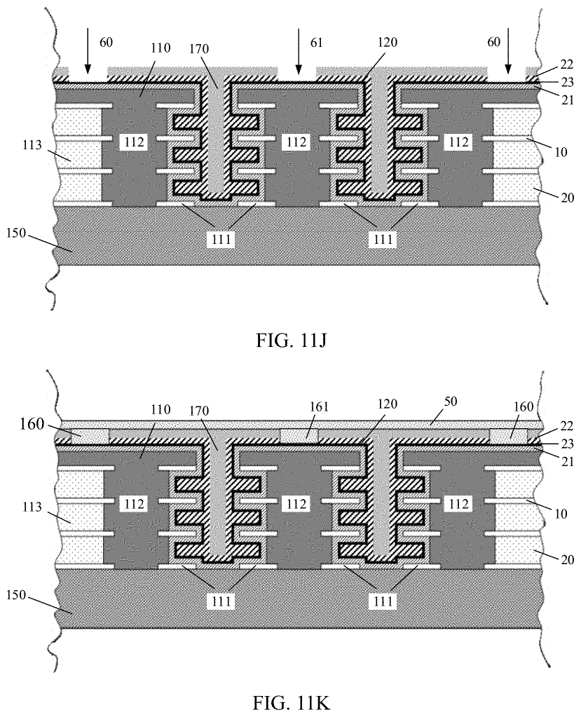

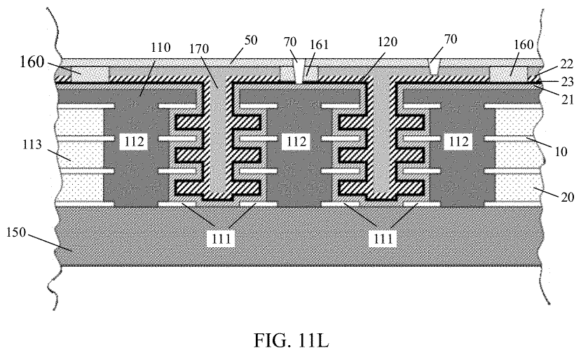

Optionally, in one embodiment, it is assumed that the laminated structure 120 includes two conductive layers and one dielectric layer. In this embodiment, the above steps 210 to 230 may specifically be a preparation process as shown in step a to step l (FIGS. 11a-11l), and the capacitor 100 as shown in FIG. 1 may be prepared. In addition, the capacitor 100 prepared based on the multi-wing structure as shown in FIG. 2 to FIG. 9 may also be prepared, which may refer to the preparation process of the capacitor as shown in step a to step l (FIGS. 11A-11L). For brevity, details are not described herein again.

Step a, select a silicon wafer as a substrate 150, and use a CVD process to alternately deposit four first material layers 10 and three second material layers 20 on the substrate 150 to form a multi-layer structure, a first material layer 10 is in direct contact with the substrate 150, as shown in FIG. 11A, for example, a first material is silicon oxide, and a second material is silicon nitride;

Step b, spin-coat a layer of photoresist on a surface of a multi-layer structure, open several gaps of the photoresist after exposure and development, then use the photoresist as a mask, and use a dry etching process to remove a film layer structure (a first material layer 10 and a second material layer 20) not covered by the photoresist to form three hollow columnar and/or grooved first structures 31 extending along a first direction, and finally remove the photoresist, as shown in FIG. 11B, where the first direction is a direction perpendicular to a substrate 150, or the first direction is a normal direction of the substrate 150;

Step c, use the dry etching process to selectively etch some of second materials exposed on a side wall of a first structure 31 along a second direction, as shown in FIG. 11C, where the second direction is perpendicular to a first direction, or the second direction is a direction parallel to a substrate 150.

Step d, use an ALD process or a CVD process to deposit a third material layer 33 on an upper surface of a multi-layer structure and in three first structures 31, as shown in FIG. 11D, for example, a third material is silicon oxide;

Of course, if an aspect ratio of a first structure 31 is relatively large, step d may also be performed step by step: first, use ALD or LPCVD with a slower deposition rate to grow a third material on an upper surface of a multi-layer structure, bottom of three first structures 31 and an inner wall of the three first structures 31 to form a conformal structure 34, and then use a PECVD process with a faster deposition rate to fill the three first structures 31 with the third material to form a third material layer 33, as shown in FIG. 11E;

Merely a structure as shown in FIG. 11D is described below as an example.

Step e, use photolithography combined with a dry etching process to form two hollow columnar and/or grooved second structures 32 extending along a first direction in a gap between first structures 31, as shown in FIG. 11F;

Step f: use two second structures 32 as release holes, and use a hot phosphoric acid solution as an etchant to remove a second material layer (silicon nitride) in contact with the release holes to form a multi-wing structure 110, as shown in FIG. 11G;

Step g, use a ALD process to deposit a layer of TiN as a conductive layer 21 on a surface of a multi-wing structure 110, then deposit a layer of aluminum oxide as a dielectric layer 23, and finally deposit a layer of TiN as a conductive layer 22 to form a laminated structure 120, as shown in FIG. 11H;

Step h, use a CVD process to deposit silicon oxide as a filling structure 170, fill and cover the entire multi-wing structure 110, as shown in FIG. 111; optionally, a MOCVD process may also be used to deposit metal tungsten as the filling structure 170; and of course, step h may not be present, and directly use the conductive layer 22 in step g to fill all the gaps;

Step i, spin-coat a layer of photoresist on a surface of a filling structure 170, open a closed annular notch of the photoresist after exposure and development, then use a dry etching process to remove a filling material and a conductive layer 22 in the notch to expose a dielectric layer 23 to form an annular groove 60 and several conductive grooves 61, as shown in FIG. 11J; of course, while preparing the annular groove 60, the conductive groove 61 may not be prepared;

Step j, use a plasma enhanced chemical vapor deposition (PECVD) process to deposit a layer of insulating material USG as an insulating layer 50, and fill an annular groove 60 and a conductive groove 61 to form an isolation ring 160 and a conductive structure 161, respectively, as shown in FIG. 11K;

Step k, use photolithography combined with a dry etching process to prepare a plurality of conductive vias 70 located on an inner region of an isolation ring 160, where some conductive vias 70 are located inside a conductive structure 161, penetrate an insulating layer 50 and a dielectric layer 23, and expose a conductive layer 21 at the bottom; other conductive vias 70 penetrate the insulating layer 50 and a filling structure 170, and expose a conductive layer 22 at the bottom, as shown in FIG. 11L;

Step l, use a physical vapor deposition (PVD) process to deposit a layer of TiN as a barrier layer and an adhesion layer on inner walls of a plurality of conductive vias 70, then use a MOCVD process to fill the plurality of conductive vias 70 with metal tungsten to form a first conductive via structure 30 and a second conductive via structure 40; next, use a chemical mechanical polishing (CMP) process to remove additional conductive materials on a surface of an insulating layer 50; then, use the PVD process to deposit a layer of Ti/TiN and a layer of metallic aluminum on the surface of the ground insulating layer 50; and finally, pattern Ti/TiN/Al using photolithography combined with an etching process to obtain a first external electrode 130 and a second external electrode 140 of a capacitor, the capacitor as shown in FIG. 1.

It should be noted that shapes of different first structures 31 among the above three first structures 31 may be the same or different, which is not limited in the present application. In the same way, shapes of different second structures 32 in the above two second structures 32 may be the same or different, which is not limited in the present application.

Therefore, in a method for producing a capacitor provided in the embodiments of the present application, M limit slot(s) are formed on an outer side wall of N support structure(s) in a multi-wing structure, and M wing structure(s) in the multi-wing structure are fixed on outside of the support structure through the M limit slot(s). In a wet release process and the subsequent cleaning process, the wing structure is not easy to fall off due to action of surface tension, so that mechanical stability and mechanical robustness of the M wing structure(s) may be improved, and the mechanical stability of the multi wing structure is improved.

A person skilled in the art can understand that the preferred embodiments of the present application are described in detail above with reference to the accompanying drawings. However, the present application is not limited to specific details in the foregoing embodiments. Within the technical concept of the present application, the technical solution of the present application may carry out a variety of simple variants, all of which are within the scope of protection of the present application.

In addition, it should be noted that various specific technical features described in the foregoing specific embodiments may be combined in any suitable manner under the condition of no contradiction. In order to avoid unnecessary repetition, various possible combination ways will not be separately described in the present application.

In addition, any combination may be made between various embodiments of the present application without departing from the idea of the present application, it should also be regarded as the disclosure of the present application.

What is claimed is:

1. A capacitor, comprising:
a multi-wing structure, the multi-wing structure comprises N groups of wing structures and N support structures, wherein each group of the wing structures comprises M wing structures arranged in parallel, M limit slots are formed on an outer side wall of the support structure, the M wing structures are fixed on outside of the support structure through the M limit slots, respectively, and M and N are positive integers;
a laminated structure, the laminated structure covers the multi-wing structure and comprises at least one dielectric layer and a plurality of conductive layers, and the at least one dielectric layer and the plurality of conductive layers form a structure that a conductive layer and a dielectric layer are alternated with each other;
at least one first external electrode, and the first external electrode is electrically connected to part or all of odd-number conductive layers in the plurality of conductive layers; and
at least one second external electrode, and the second external electrode is electrically connected to part or all of even-number conductive layers in the plurality of conductive layers.

2. The capacitor according to claim 1, wherein a side wall of the support structure is recessed inwards to form the M limit slots on the outer side wall of the support structure, or a side wall of the support structure protrudes outwards to form the M limit slots on the outer side wall of the support structure.

3. The capacitor according to claim 1, wherein the support structure is columnar or sheet.

4. The capacitor according to claim 1, wherein the support structure is hollow columnar or grooved.

5. The capacitor according to claim 1, wherein the support structure is a T-shaped structure.

6. The capacitor according to claim 1, wherein the capacitor further comprises: an annular structure, and the annular structure is located outside of the N support structures and the N groups of wing structures.

7. The capacitor according to claim 6, wherein the annular structure is formed by alternately stacking M first material layers and M−1 second material layers, and the wing structure is formed of the first material.

8. The capacitor according to claim 1, wherein part or all of the conductive layers in the plurality of conductive layers are conformal with the multi-wing structure.

9. The capacitor according to claim 1, wherein one part of the conductive layer in the plurality of conductive layers is conformal with the multi-wing structure, and the other part of the conductive layer is complementary to the multi-wing structure in shape.

10. The capacitor according to claim 1, further comprising:
an isolation ring located above outside of the N support structures, and the isolation ring is configured to isolate the laminated structure into two parts, an inner side and an outer side, and the first external electrode and the second external electrode are merely electrically connected to a part of the laminated structure located at the inner side of the isolation ring.

11. The capacitor according to claim 10, further comprising:
at least one first conductive via structure and at least one second conductive via structure, wherein
the first conductive via structure is located in the isolation ring, and the second conductive via structure is located outside the isolation ring near a center of the capacitor; or the first conductive via structure and/or the second conductive via structure is located outside the isolation ring near a center of the capacitor; and
the first external electrode is electrically connected to part or all of odd-number conductive layers in the plurality of conductive layers through the at least one first conductive via structure, and the second external electrode is electrically connected to part or all of even-number conductive layers in the plurality of conductive layers through the at least one second conductive via structure.

12. The capacitor according to claim 1, wherein the multi-wing structure is made of a conductive material, and the second external electrode is electrically connected to the multi-wing structure.

13. The capacitor according to claim 1, further comprising: a filling structure, and the filling structure covers the laminated structure and fills a gap formed by the laminated structure.

14. The capacitor according to claim 1, wherein the capacitor further comprises: a substrate arranged under the multi-wing structure;
wherein a wing structure in the N groups of wing structures in contact with the substrate has a discontinuous region between different support structures, and the substrate forms a substrate groove at the discontinuous region, and the laminated structure is further arranged inside the substrate groove.

15. The capacitor according to claim 14, wherein the support structure extends into the substrate.

16. The capacitor according to claim 1, wherein the first external electrode and/or the second external electrode is electrically connected to a conductive layer in the plurality of conductive layers through an interconnection structure.

17. The capacitor according to claim 16, wherein the interconnection structure comprises at least one isolating layer, at least one first conductive via structure, and at least one second conductive via structure, wherein the first conductive via structure and the second conductive via structure penetrate the at least one insulating layer, the first external electrode is electrically connected to part or all of odd-number conductive layers in the plurality of conductive layers through the at least one first conductive via structure, and the second external electrode is electrically connected to part or all of even-number conductive layers in the plurality of conductive layers through the at least one second conductive via structure.

18. A method for producing a capacitor, comprising:
preparing a multi-wing structure above a substrate, the multi-wing structure comprises N groups of wing structures and N support structures, wherein each group of the wing structures comprises M wing structures arranged in parallel, M limit slots are formed on an outer side wall of the support structure, the M wing structures are fixed on outside of the support structure through the M limit slots, respectively, and M and N are positive integers;
preparing a laminated structure on a surface of the multi-wing structure, the laminated structure covers the multi-wing structure and comprises at least one dielectric layer and a plurality of conductive layers, and the at least one dielectric layer and the plurality of conductive layers form a structure that a conductive layer and a dielectric layer are alternated with each other; and
preparing at least one first external electrode and at least one second external electrode, wherein the first external electrode is electrically connected to part or all of odd-number conductive layers in the plurality of conductive layers, and the second external electrode is electrically connected to part or all of even-number conductive layers in the plurality of conductive layers.

19. The method according to claim 18, wherein the support structure is a T-shaped structure.

20. The method according to claim 19, wherein the preparing a multi-wing structure above a substrate comprises:
preparing a multi-layer structure above the substrate, the multi-layer structure comprises M first material layers and M−1 second material layers, and the M first material layers and the M−1 second material layers form a structure that a first material layer and a second material layer are alternated with each other, the first material layer is different from the second material, and the first material layer is in direct contact with the substrate;
based on the multi-layer structure, preparing N first grooves extending along a first direction, and removing part of the second material exposed in the N first grooves, so as to form N hollow columnar or grooved first structures made of the first material, and the first direction is a direction perpendicular to the substrate;
depositing a third material on an upper surface of the multi-layer structure and in the N first structures; and
based on the multi-layer structure, preparing N second grooves extending along the first direction, and removing the second material layer exposed in the N second grooves, thus forming N hollow columnar or grooved second structures made of the first material, so as to prepare the multi-wing structure.
